(19) United States
(12) Patent Application Publication
(10) Pub. No.: US 2025/0276521 A1
(43) Pub. Date: Sep. 4, 2025

(54) LIQUID EJECTION HEAD

(71) Applicant: SEIKO EPSON CORPORATION, Tokyo (JP)

(72) Inventors: Harunobu KOIKE, MATSUMOTO-SHI (JP); Toshihiro SHIMIZU, FUJIMI-MACHI (JP); Takatoshi YAMAZAKI, SHIOJIRI-SHI (JP)

(21) Appl. No.: 19/069,354

(22) Filed: Mar. 4, 2025

(30) Foreign Application Priority Data
Mar. 4, 2024 (JP) 2024-031941
Sep. 30, 2024 (JP) 2024-170145

(51) Int. Cl. B41J 2/14; H10N 30/853

(52) U.S. Cl. CPC B41J 2/14209; H10N 30/8536; B41J 2002/14491

(57) ABSTRACT

A liquid ejection head includes: a vibration plate and a piezoelectric element, having a first electrode, a piezoelectric layer, and a second electrode which are laminated in a lamination direction, the piezoelectric layer is formed of a piezoelectric material containing lead as a constituent element, the first electrode has an electrode layer and a lead-containing layer disposed between the electrode layer and the vibration plate and containing lead, and when, of two regions arranged in a crossing direction, which is a direction crossing the lamination direction, when seen in the lamination direction, a region farther away from a center of the first electrode is a first region and a region closer to the center of the first electrode is a second region, a lead content percentage in the lead-containing layer in the first region is lower than a lead content percentage in the lead-containing layer in the second region.

The present application is based on, and claims priority from JP Application Serial Number 2024-031941, filed Mar. 4, 2024 and JP Application Serial Number 2024-170145, filed Sep. 30, 2024, the disclosures of which are hereby incorporated by reference herein in their entirety.

### BACKGROUND

### 1. Technical Field

The present disclosure relates to a liquid ejection head.

### 2. Related Art

A liquid ejection apparatus, typified by a piezoelectric ink jet printer, uses a liquid ejection head that ejects liquid such as ink. For example, the head described in JP-A-2002-319714 has a vibration plate and a piezoelectric element. The piezoelectric element is formed by a lower electrode, a piezoelectric film, and an upper electrode laminated sequentially on the vibration plate.

The head described in JP-A-2002-319714 has room for improvement in reducing damage such as cracking at the end portion of the lower electrode.

### SUMMARY

An aspect of the present disclosure to solve the above problem provides a liquid ejection head including: a piezoelectric element having a first electrode, a piezoelectric layer, and a second electrode and a vibration plate, in which the first electrode, the piezoelectric layer, and the second electrode are laminated in this order in a lamination direction which is a direction directed from the vibration plate to the piezoelectric element, the piezoelectric layer is formed of a piezoelectric material containing lead as a constituent element, the first electrode has an electrode layer and a lead-containing layer disposed between the electrode layer and the vibration plate and containing lead, and when, of two regions arranged in a crossing direction, which is a direction crossing the lamination direction, when seen in the lamination direction, a region farther away from a center of the first electrode is a first region and a region closer to the center of the first electrode is a second region, a first lead content percentage in the lead-containing layer in the first region is higher than a second lead content percentage in the lead-containing layer in the second region.

### BRIEF DESCRIPTION OF THE DRAWINGS

FIG. 1 is a configuration diagram schematically showing a liquid ejection apparatus having a liquid ejection head according to an embodiment.

FIG. 2 is an exploded perspective view of the liquid ejection head according to the embodiment.

FIG. 3 is a sectional view taken along the III-III line in FIG. 2.

FIG. 4 is a plan view showing part of the liquid ejection head according to the embodiment.

FIG. 5 is a sectional view taken along the V-V line in FIG. 4.

FIG. 6 is an enlarged view of part VI in FIG. 5.

### DESCRIPTION OF EMBODIMENTS

Preferred embodiments according to the present disclosure are described below with reference to the drawings attached hereto. Note that the dimensions and scales of components in the drawings differ from the actual ones as needed, and some portions are depicted schematically in order to facilitate understanding. Also, the scope of the present disclosure is not limited to those modes of the present disclosure unless the following description specifically states so.

Note that the following description uses an X-axis, a Y-axis, and a Z-axis that are orthogonal to one another, as needed. Also, in the following description, one direction along the X-axis is an X1-direction, and a direction opposite from the X1-direction is an X2-direction. Similarly, directions along the Y-axis that are opposite from each other are a Y1-direction and a Y2-direction. Also, directions along the Z-axis that are opposite from each other are a Z1-direction and a Z2-direction. The Z1-direction is an example of the “lamination direction.” Also, a view seen in a direction along the Z-axis may be referred to as a “plan view”.

The Z-axis is typically a vertical axis, and the Z2-direction corresponds to a vertically downward direction. However, the Z-axis does not have to be a vertical axis. Also, although the X-axis, the Y-axis, and the Z-axis are typically orthogonal to one another, the present disclosure is not limited to this as long as they intersect at an angle in the range of, for example, no less than 80° and no more than 100°.

### 1. Embodiment

### 1-1. Overall Configuration of a Liquid Ejection Apparatus

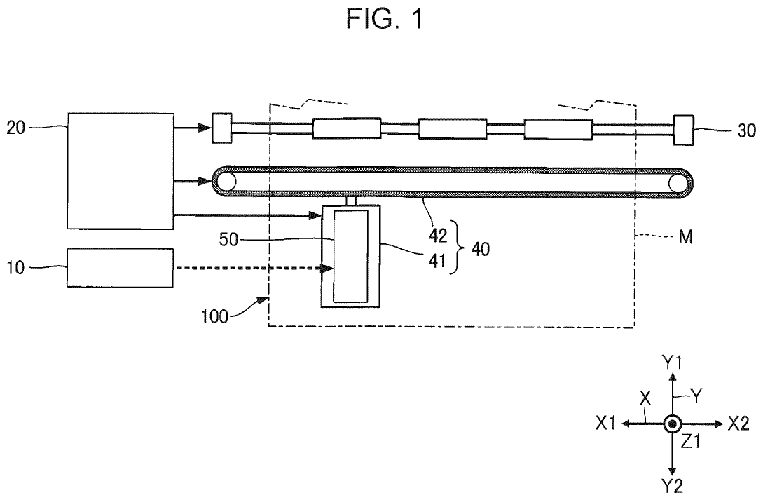

FIG. 1 is a configuration diagram schematically showing a liquid ejection apparatus 100 having a liquid ejection head 50 according to an embodiment. The liquid ejection apparatus 100 is an ink jet printing apparatus that ejects droplets of ink, which is an example of the liquid, to a medium M. The medium M is typically a print sheet. Note that the medium M is not limited to a print sheet, and any material, such as, e.g., a resin film or a cloth, may be used for printing.

As shown in FIG. 1, the liquid ejection apparatus 100 has a liquid container 10, a control unit 20, a conveyance mechanism 30, a movement mechanism 40, and the liquid ejection head 50.

The liquid container 10 is a container storing ink. Example specific modes of the liquid container 10 include a cartridge attachable to and detachable from the liquid ejection apparatus 100, a bag-shaped ink pack formed of a flexible film, and an ink tank that can be replenished with ink. Note that the type of ink stored in the liquid container 10 is not limited to any particular type and may be any type.

The control unit 20 includes, for example, a processing circuit such as a central processing unit (CPU) or a field-programmable gate array (FPGA) and a memory circuit such as semiconductor memory, and controls the operation of each component in the liquid ejection apparatus 100.

As controlled by the control unit 20, the conveyance mechanism 30 conveys the medium M in the Y2-direction. As controlled by the control unit 20, the movement mechanism 40 causes the liquid ejection head 50 to reciprocate in the X1-direction and the X2-direction. In the example shown in FIG. 1, the movement mechanism 40 has a substantially box-shaped carriage 41 housing the liquid ejection head 50 and a conveyor belt 42 to which the carriage 41 is fixed. Note that the number of liquid ejection heads 50 mounted to the carriage 41 is not limited to one and may be more than one. Also, in addition to the liquid ejection head 50, the liquid container 10 described earlier may be mounted to the carriage 41.

As controlled by the control unit 20, the liquid ejection head 50 ejects ink supplied from the liquid container 10 to the medium M in the Z2-direction from each of a plurality of nozzles. This ejection is performed in concurrence with the conveyance of the medium M by the conveyance mechanism 30 and the reciprocating movement of the liquid ejection head 50 by the movement mechanism 40, thereby forming an image on the surface of the medium M with the ink.

### 1-2. Overall Configuration of the Liquid Ejection Head

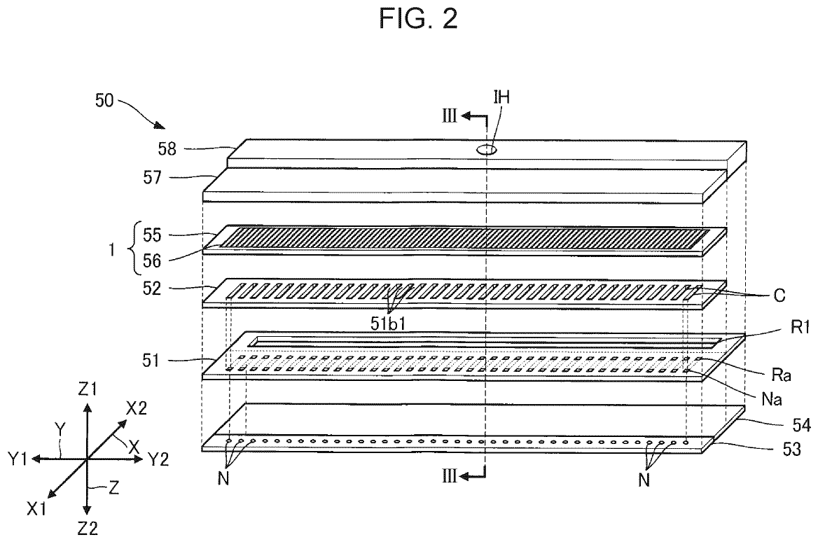

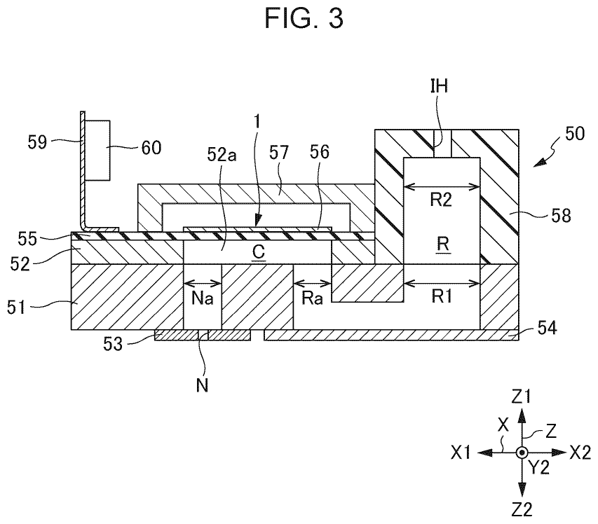

FIG. 2 is an exploded perspective view of the liquid ejection head 50 according to the embodiment. FIG. 3 is a sectional view taken along the III-III line in FIG. 2. As shown in FIGS. 2 and 3, the liquid ejection head 50 has a flow channel substrate 51, a pressure chamber substrate 52, a nozzle plate 53, a vibration absorber 54, a vibration plate 55, a plurality of piezoelectric elements 56, a seal plate 57, a case 58, and a wiring substrate 59. The vibration plate 55 and the piezoelectric element 56 form an actuator 1. In this way, the liquid ejection head 50 has the actuator 1 including the piezoelectric element 56 and the vibration plate 55.

The pressure chamber substrate 52, the vibration plate 55, the plurality of piezoelectric elements 56, the case 58, and the seal plate 57 are disposed in a region located on the Z1-direction side of the flow channel substrate 51. Meanwhile, the nozzle plate 53 and the vibration absorber 54 are disposed in a region located on the Z2-direction side of the flow channel substrate 51. The components of the liquid ejection head 50 are roughly plate members elongated in a direction along the Y-axis and are joined to each other using, for example, an adhesive.

As shown in FIG. 2, the nozzle plate 53 is a plate-shaped member provided with a plurality of nozzles N arrayed in a direction along the Y-axis. Each nozzle N is a through-hole through which ink passes. In this way, the nozzle plate 53 has the plurality of nozzles N that produce jets of ink. The nozzle plate 53 is manufactured by, for example, processing a single-crystal silicon substrate using a semiconductor manufacturing technique employing a processing technique such as dry etching or wet etching. However, other publicly known methods and materials may be used as needed to manufacture the nozzle plate 53.

The flow channel substrate 51 is a plate-shaped member forming flow channels of ink. As shown in FIGS. 2 and 3, the flow channel substrate 51 is provided with an opening portion R1, a plurality of supply flow channels Ra, and a plurality of communication flow channels Na. The opening portion R1 is an elongated through-hole extending in a direction along the Y-axis continuously over the plurality of nozzles N in a plan view seen in a direction along the Z-axis. Meanwhile, the supply flow channels Ra and the communication flow channels Na are through-holes provided for the individual nozzles N. The plurality of supply flow channels Ra each communicate with the opening portion R1. Similarly to the nozzle plate 53 described above, the flow channel substrate 51 is manufactured by, for example, processing a single-crystal silicon substrate using a semiconductor manufacturing technique. However, other publicly known methods and materials may be used as needed to manufacture the flow channel substrate 51.

The pressure chamber substrate 52 is a plate-shaped member where a plurality of pressure chambers C are formed in correspondence to the plurality of nozzles N. The pressure chambers C are spaces called cavities, located between the flow channel substrate 51 and the vibration plate 55 and used to apply pressure to ink filled into the pressure chambers C. The plurality of pressure chambers C are arrayed in a direction along the Y-axis. Each pressure chamber C is formed by a hole 52a opening to both surfaces of the pressure chamber substrate 52 and has an elongated shape extending in a direction along the X-axis. In this way, the pressure chamber substrate 52 has the plurality of pressure chambers C communicating with the nozzles N. Each pressure chamber C, at its end on the X2-direction side, communicates with a corresponding one of the supply flow channels Ra. Meanwhile, each pressure chamber C, at its end on the X1-direction side, communicates with a corresponding one of the communication flow channel Na. Similarly to the nozzle plate 53 described above, the pressure chamber substrate 52 is manufactured by, for example, processing a single-crystal silicon substrate using a semiconductor manufacturing technique. However, other publicly known methods and materials may be used as needed to manufacture the pressure chamber substrate 52.

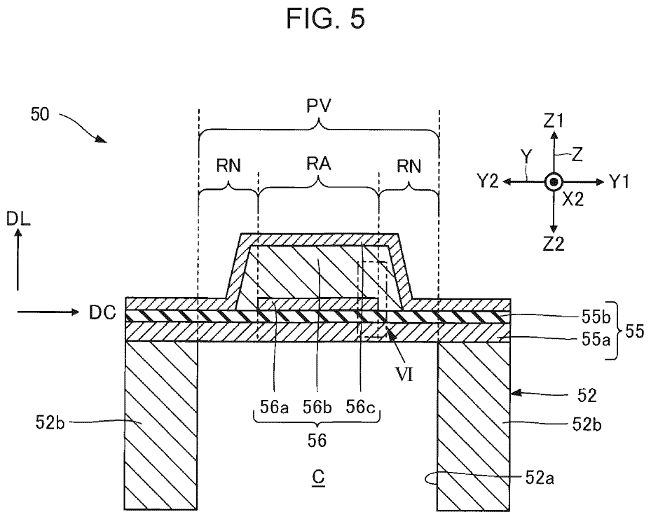

The vibration plate 55 is disposed at the surface of the pressure chamber substrate 52 which faces the Z1-direction. The vibration plate 55 is a plate-shaped member which is elastically deformable and is connected to the piezoelectric elements 56. Note that details of the vibration plate 55 will be described later based on FIG. 5.

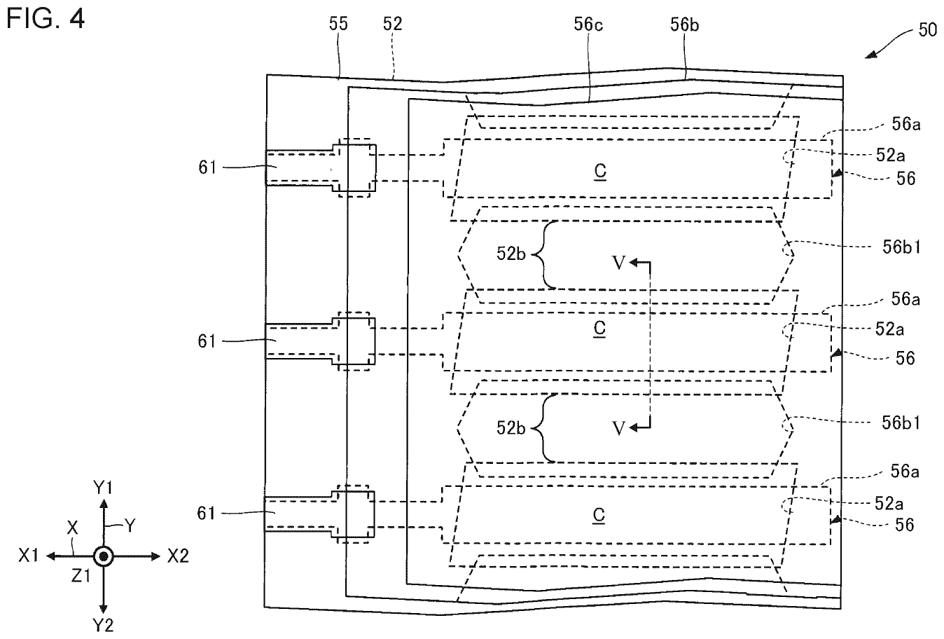

The piezoelectric elements 56 are disposed at the surface of the vibration plate 55 which faces the Z1-direction. Each piezoelectric element 56 is a passive element that deforms upon supply of a drive signal and has an elongated shape extending in a direction along the X-axis. Note that one piezoelectric element 56 is provided for every pressure chamber, and the plurality of piezoelectric elements 56 are arrayed in a direction along the Y-axis in correspondence to the plurality of pressure chambers C. The vibration plate 55 vibrating in conjunction with deformation of the piezoelectric elements 56 fluctuates the pressure inside the pressure chambers C, causing the ink to be ejected from the nozzles N. Note that details of the piezoelectric elements 56 will be described later based on FIGS. 4 to 6.

The case 58 is a case for storing ink to be supplied to the plurality of pressure chambers C and is joined, by means of an adhesive or the like, to the surface of the flow channel substrate 51 which faces the Z1-direction. The case 58 is formed by, for example, a resin material and is manufactured by injection molding. The case 58 is provided with a storage portion R2 and an inlet IH. The storage portion R2 is a concave portion whose outer shape conforms to the opening portion R1 of the flow channel substrate 51. The inlet IH is a through-hole communicating with the storage portion R2. The space formed by the opening portion R1 and the storage portion R2 functions as a liquid storage chamber R as a reservoir for storing ink. Ink from the liquid container 10 is supplied to the liquid storage chamber R through the inlet IH.

The vibration absorber 54 is a component for absorbing fluctuations in the pressure inside the liquid storage chamber R. The vibration absorber 54 is, for example, a compliance substrate which is a flexible, elastically deformable sheet member. The vibration absorber 54 is disposed at the surface of the flow channel substrate 51 which faces the Z2-direction, closing the opening portion R1 and the plurality of supply flow channels Ra of the flow channel substrate 51 to form the bottom surface of the liquid storage chamber R.

The seal plate 57 is a structure that not only protects the plurality of piezoelectric elements 56 but also reinforces the mechanical strength of the pressure chamber substrate 52 and the vibration plate 55. The seal plate 57 is joined to a surface of the vibration plate 55 using, for example, an adhesive. The seal plate 57 is provided with a concave portion for housing the plurality of piezoelectric elements 56.

The wiring substrate 59 is joined to the surface of the pressure chamber substrate 52 or the vibration plate 55 which faces the Z1-direction. The wiring substrate 59 is a mount component where a plurality of interconnections are formed to electrically connect the control unit 20 and the liquid ejection head 50. The wiring substrate 59 is, for example, a flexible wiring substrate such as a flexible printed circuit (FPC) or a flexible flat cable (FFC). A drive circuit 60 for driving the piezoelectric elements 56 is mounted on the wiring substrate 59. The drive circuit 60 selectively supplies each piezoelectric element 56 with a drive signal for driving the piezoelectric element 56 via the wiring substrate 59.

### 1-3. Details of the Vibration Plate and the Piezoelectric Elements

FIG. 4 is a plan view showing part of the liquid ejection head 50 according to the embodiment. FIG. 5 is a sectional view taken along the V-V line in FIG. 4. Based on FIGS. 4 and 5, the following describes the pressure chamber substrate 52, the piezoelectric element 56, and the vibration plate 55 in this order.

As shown in FIGS. 4 and 5, the pressure chamber substrate 52 is provided with the holes 52a forming the pressure chambers C. The pressure chamber substrate 52 is accordingly provided with a wall-shaped partitioning wall 52b between each pair of adjacent holes 52a, the partitioning wall 52b extending in a direction along the X-axis. The pressure chamber substrate 52 is manufactured by, for example, processing a single-crystal silicon substrate using a semiconductor manufacturing technique. FIG. 4 shows, using broken lines, the plan-view shapes of the holes 52a formed in a substrate of single-crystal silicon with a (110) plane orientation using anisotropic etching. Note that the plan-view shapes of the hole 52a are not limited to the example shown in FIG. 4 and may be any shape.

The pressure chambers C are formed after the formation of the piezoelectric elements 56. The pressure chambers C are formed by, for example, performing anisotropic etching on one of the surfaces of the single-crystal silicon substrate having the piezoelectric element 56 already formed therein, the one surface being opposite from the surface where the piezoelectric elements 56 are formed. In this anisotropic etching, for example, a potassium hydroxide (KOH) solution or the like is used as an etching liquid. Also, in a case where an elastic layer 55a is formed of silicon oxide, the elastic layer 55a functions as a stop layer for stopping the anisotropic etching. After the formation of the pressure chambers C, the flow channel substrate 51 and the like are joined to the pressure chamber substrate 52 with, for example, an adhesive. Note that after the formation of the piezoelectric element 56, the surface of the single-crystal silicon substrate opposite from the surface where the piezoelectric elements 56 are formed is polished by chemical mechanical polishing (CMP) or the like as needed to flatten the surface and adjust the thickness of the substrate.

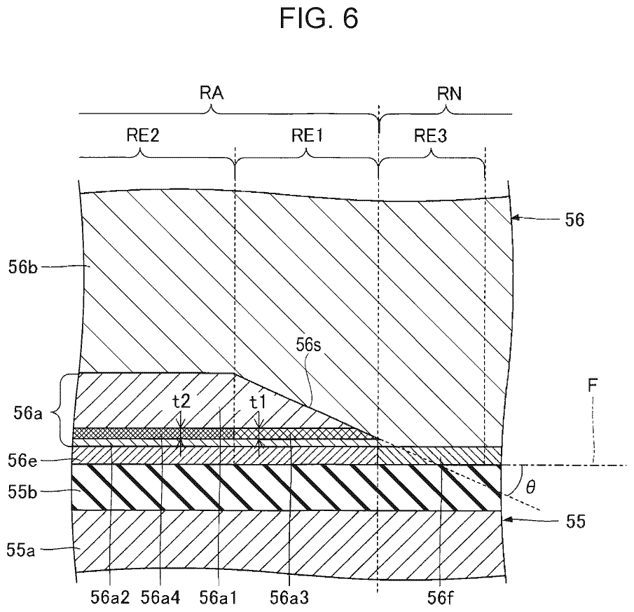

As shown in FIG. 4, the piezoelectric elements 56 overlap with the pressure chambers C in a plan view. As shown in FIG. 5, the piezoelectric element 56 has a first electrode 56a, a piezoelectric layer 56b, and a second electrode 56c, and they are laminated in this order in the Z1-direction. Specifically, the first electrode 56a, the piezoelectric layer 56b, and the second electrode 56c are laminated in this order in a lamination direction DL, which is a direction directed from the vibration plate 55 to the piezoelectric element 56. Note that the piezoelectric element 56 has, in addition to the first electrode 56a, the piezoelectric layer 56b, and the second electrode 56c, a first lead diffusion inhibition layer 56e and a second lead diffusion inhibition layer 56f, as will be described later based on FIG. 6.

The first electrodes 56a are individual electrodes disposed for the respective piezoelectric elements 56 and spaced away from one another. Specifically, a plurality of first electrodes 56a extending in a direction along the X-axis are arrayed in a direction along the Y-axis with spaces in between. The first electrode 56a of each piezoelectric element 56 is supplied with a drive signal including a predetermined voltage pulse from the control unit 20. Note that details of the first electrode 56a will be described later based on FIG. 6.

For example, the first electrode 56a is formed after the formation of the vibration plate 55 and the first lead diffusion inhibition layer 56e to be described later, using a publicly known film formation technique such as sputtering and publicly known processing techniques such as photolithography and etching. Also, the thickness of the first electrode 56a is, for example, approximately 100 nm.

In the example shown in FIGS. 4 and 5, the piezoelectric layer 56b has a belt shape extending in a direction along the Y-axis continuously over the plurality of piezoelectric elements 56. In the example shown in FIG. 4, in regions corresponding to the gaps between the adjacent pressure chambers C in a plan view, the piezoelectric layer 56b is provided with through-holes 56b1 penetrating through the piezoelectric layer 56b and extending in a direction along the X-axis. Thus, in a sectional view shown in FIG. 5, the piezoelectric layer 56b is provided individually for each piezoelectric element 56. Note that, in a sectional view shown in FIG. 5, the piezoelectric layer 56b may be provided individually for the plurality of piezoelectric elements 56.

The piezoelectric layer 56b is formed of a piezoelectric material containing lead as a constituent element. The piezoelectric material has a perovskite crystal structure expressed by a general composition formula ABO₃ and is, for example, lead zirconate titanate (Pb (Zr, Ti)O₃). Also, in addition to lead (Pb), the piezoelectric layer 56b may contain at least one element selected from vanadium (V), niobium (Nb), tantalum (Ta), nickel (Ni), phosphorus (P), arsenic (As), antimony (Sb), and bismuth (Bi).

For example, the piezoelectric layer 56b is formed after the formation of the first electrode 56a, by forming a uniform piezoelectric precursor layer through a sol-gel process, baking and crystalizing the precursor layer, and then performing patterning by etching such as reactive ion etching (RIE) or ion milling.

The second electrode 56c is a belt-shaped common electrode extending in a direction along the Y-axis continuously over the plurality of piezoelectric elements 56. The second electrode 56c is supplied with a predetermined constant potential.

The second electrode 56c is formed of, for example, iridium (Ir). Note that a material forming the second electrode 56c is not limited to iridium, and may be, for example, a metal material such as titanium (Ti), platinum (Pt), aluminum (Al), nickel (Ni), gold (Au), or copper (Cu) or a conductive oxide such as lanthanum nickel oxide (LaNiO₃: LNO) or strontium ruthenium oxide (SrRuO₃: SRO). Also, the second electrode 56c may use a single one of these metal materials or may combine two or more of them using a mode such as lamination.

For example, the second electrode 56c is formed after the formation of the piezoelectric layer 56b, using a publicly known film formation technique such as sputtering and publicly known processing techniques such as photolithography and etching. Also, the thickness of the second electrode 56c is, for example, approximately 100 nm.

In the piezoelectric element 56 thus described, upon application of a voltage between the first electrode 56a and the second electrode 56c, the piezoelectric layer 56b deforms due to the inverse piezoelectric effect. The vibration plate 55 is connected to the piezoelectric element 56 and vibrates as the piezoelectric layer 56b deforms.

As shown in FIG. 5, the vibration plate 55 has the elastic layer 55a and an insulating layer 55b, which are laminated in this order in the Z1-direction. The insulating layer 55b is disposed offset to a position closer to the first electrode 56a in the direction of the thickness of the vibration plate 55.

The elastic layer 55a is a film formed of, for example, silicon oxide (SiO₂). Note that a material forming the elastic layer 55a is not limited to silicon oxide, and may be, for example, a material containing one element or two or more elements selected from titanium (Ti), silicon (Si), aluminum (Al), tantalum (Ta), chromium (Cr), iridium (Ir), hafnium (Hf), zirconium (Zr), and carbon (C), in an elemental form, an oxide form, or a nitride form.

The thickness of the elastic layer 55a is determined based on, e.g., the thickness and width of the vibration plate 55 and not limited to any particular thickness, but is, for example, in the range of no less than 100 nm and no more than 3000 nm.

The insulating layer 55b is a film formed of, for example, zirconium oxide (ZrO₂) and contains zirconium (Zr). The insulating layer 55b thus containing zirconium is disposed offset to a position closer to the first electrode 56a in the thickness direction of the vibration plate 55, which can inhibit bonding of the lead contained in the first electrode 56a with the material forming the elastic layer 55a. Note that the material forming the insulating layer 55b is not limited to zirconium oxide and may be, for example, a material containing one element or two or more elements selected from titanium (Ti), aluminum (Al), tantalum (Ta), chromium (Cr), hafnium (Hf), and zirconium (Zr), in an oxide or nitride form.

The thickness of the insulating layer 55b is determined based on, e.g., the thickness and width of the vibration plate 55 and not limited to any particular thickness, but is, for example, in the range of no less than 100 nm and no more than 2000 nm.

In the example shown in FIG. 5, the elastic layer 55a and the insulating layer 55b are in contact with each other. Note that another layer may be interposed between the elastic layer 55a and the insulating layer 55b, such as an adhesion layer for enhancing the adhesion between the elastic layer 55a and the insulating layer 55b. A material forming the adhesion layer is, for example, TiO_{X}, AlO_{X}, CrO_{X}, or TiN. The thickness of the adhesion layer is determined based on the thickness and width of the vibration plate 55 and not limited to any particular thickness, but is, for example, in the range of no less than 20 nm and no more than 2000 nm.

The elastic layer 55a and the insulating layer 55b thus described are formed as films in this order on the single-crystal silicon substrate for forming the pressure chamber substrate 52. For example, in a case where the elastic layer 55a is formed of silicon oxide, the elastic layer 55a is formed by thermal oxidization of one of the surfaces of the single-crystal silicon substrate. For example, in a case where the insulating layer 55b is formed of zirconium oxide, the insulating layer 55b is formed by thermal oxidization of a zirconium layer formed by sputtering on the elastic layer 55a.

Note that methods for forming the plurality of films forming the vibration plate 55 are not limited to the examples described above, and any methods may be used. For example, chemical vapor deposition (CVD) or the like may be used to form at least part of the elastic layer 55a. Also, in a case where an adhesion layer is provided between the elastic layer 55a and the insulating layer 55b, the adhesion layer is formed by thermal oxidation of a layer of chromium, titanium, aluminum, or the like formed by sputtering on the elastic layer 55a. The thermal oxidation for forming the adhesive layer may be performed concurrently with the thermal oxidation for forming the insulating layer 55b. Also, the formation of the adhesive layer is not limited to the method using thermal oxidation and may be performed using, for example, CVD, atomic layer deposition (ALD), or the like.

The actuator 1 formed by the vibration plate 55 and the piezoelectric element 56 thus described has a vibration region PV that vibrates when the piezoelectric element 56 is driven. The vibration region PV is part of the actuator 1 and is a portion overlapping with the pressure chamber C in a plan view.

The vibration region PV is divided into an active portion RA and a non-active portion RN. The active portion RA is part of the actuator 1 and is a region overlapping with the pressure chamber C, the first electrode 56a, the piezoelectric layer 56b, and the second electrode 56c when seen in a direction along the Z-axis. The non-active portion RN is part of the actuator 1 and is a region overlapping with the pressure chamber C when seen in a direction along the Z-axis and being different from the active portion RA. The non-active portion RN, when seen in a direction along the Z-axis, is a region where the first electrode 56a is not provided and where at least one of the piezoelectric layer 56b and the second electrode 56c overlaps with the pressure chamber C.

FIG. 6 is an enlarged view of part VI in FIG. 5. As shown in FIG. 6, the first electrode 56a has an electrode layer 56a1, a lead-containing layer 56a2, a first mixture layer 56a3, and a second mixture layer 56a4.

The electrode layer 56al has, for example, a layer formed of platinum (Pt), a layer formed of iridium (Ir), and a layer formed of titanium (Ti). In other words, the electrode layer 56al contains platinum, iridium, and titanium. Platinum is an electrode material having good conductivity. Thus, using platinum as a material forming the first electrode 56a can lower the resistance of the first electrode 56a. Also, in formation of the piezoelectric layer 56b, the layer formed of titanium and island-shaped Ti acts as a crystal nucleus and controls the orientation of the piezoelectric layer 56b, enhancing the crystallinity and orientation of the piezoelectric layer 56b. Note that in place of or in addition of these layers, a layer formed of a different metal material or conductive oxide may be provided. Also, such a layer may have a layer of a mixture of a plurality of metal materials or a layer formed of an alloy.

The thickness of the electrode layer 56al may be, for example, in the range of no less than 90 nm and no more than 160 nm.

The lead-containing layer 56a2 is disposed between the electrode layer 56al and the vibration plate 55 and contains lead. The lead-containing layer 56a2 forms the lowermost layer of the first electrode 56a in the lamination direction DL. The thickness of the lead-containing layer 56a2 is, for example, in the range of no less than 5 nm and no more than 25 nm.

Also, the lead-containing layer 56a2 is a layer with a higher lead content percentage than the electrode layer 56a1. When lead content percentage are measured using, for example, secondary ion mass spectrometry, energy dispersive X-ray analysis, or the like, the lead-containing layer 56a2 has a higher lead content percentage than the other portions of the electrode layer 56a1.

The lead-containing layer 56a2 contains a metal element other than lead. For example, the lead-containing layer 56a2 contains a metal material contained in the electrode layer 56a1. Note that the lead-containing layer 56a2 may contain a different metal material. Also, the lead contained in the lead-containing layer 56a2 may be present in an elemental or alloyed form or in an oxide, nitride, or oxynitride form.

Of two regions arranged in a crossing direction DC, which is a direction crossing the lamination direction DL, when seen in the lamination direction DL, a region farther from the center of the first electrode 56a is a first region RE1 and a region closer to the center of the first electrode 56a is a second region RE2. Then, the lead content percentage in the lead-containing layer 56a2 in the first region RE1 is lower than the lead content percentage in the lead-containing layer 56a2 in the second region RE2.

The size of the first region RE1 in the crossing direction DC is determined based on, e.g., the thickness and width of the first electrode 56a and not limited to any particular size, but is, for example, in the range of no less than 180 nm and no more than 320 nm. In other words, the first region RE1 is a region extending in the crossing direction DC from the end portion of the first electrode 56a toward its center for a distance in the range of no less than 180 nm and no more than 320 nm.

Although not shown, the first region RE1 is provided on both sides of the active portion RA in the crossing direction DC. Thus, the second region RE2 is a region sandwiched by the first regions RE1 in the crossing direction DC.

In the example shown in FIG. 6, the first electrode 56a measures approximately 40 μm in width and approximately 110 nm in thickness, and the size of the first region RE1 in the crossing direction DC is approximately 240 nm. The size of the first region RE1 may be determined based on the thickness of the first electrode 56a. For example, the size of the first region RE1 is preferably no less than two times and less than four times the thickness of the first electrode 56a.

Note that in the example shown in FIG. 6, the first electrode 56a has a slant surface 56s at an end portion in the crossing direction DC, such that its surface facing the Z1-direction slants toward the vibration plate 55. In this example, the slant surface 56s is located in the first region RE1.

When lead content percentages are measured using, for example, secondary ion mass spectrometry, energy dispersive X-ray analysis, or the like, the lead content percentage in the lead-containing layer 56a2 in the first region RE1 is lower than the lead content percentage in the lead-containing layer 56a2 in the second region RE2.

Lead content percentages in the lead-containing layer 56a2 are measured using, for example, secondary ion mass spectrometry, energy dispersive X-ray analysis, or the like. When lead content percentages in the lead-containing layer 56a2 are measured using, for example, secondary ion mass spectrometry, the contents of two or more elements including lead from the elements contained in the lead-containing layer 56a2 are measured over a region of a particular area, e.g., an area of 1 mm², in a plan view. Then, the content of lead is standardized by the sum of the contents of lead and the other element. The lead content percentage is thus calculated. Note that in a case of measuring the content of oxygen as an element other than lead, a lead content percentage may be calculated by standardization of the lead content by the oxygen content. Also, a lead content percentage may be calculated by standardization of a lead content by the content of a particular material.

A comparison between lead content percentages in the lead-containing layer 56a2 in the first region RE1 and the second region RE2 is done by a comparison of lead content percentages measured at the same position in the lamination direction DL. Also, the comparison is preferably done at the center positions in the lead-containing layer 56a2 in the first region RE1 and the second region RE2 in the crossing direction DC. Note that the comparison may be done using the averages of a plurality of lead content percentages at a plurality of locations in the lead-containing layer 56a2 in the lamination direction DL or the crossing direction DC.

The first region RE1 and the second region RE2 are included in the active portion RA. In the example shown in FIG. 6, the active portion RA is divided into the first region RE1 and the second region RE2, and the first region RE1 and the second region RE2 are adjacent to each other. Also, the first region RE1 is adjacent to the non-active portion RN. The second region RE2 is a region located toward the center of the first electrode 56a when seen in the lamination direction DL. The first region RE1 is a region located more outward than the second region RE2 when seen in the lamination direction DL.

In this way, the lead content percentage in the lead-containing layer 56a2 in the first region RE1 is lower than the lead content percentage in the lead-containing layer 56a2 in the second region RE2. In other words, the lead content in the center portion of the first electrode 56a is larger than the lead content in the end portion of the first electrode 56a. Thus, the density of the metal material forming the first electrode 56a in the first region RE1 can be increased. This enables the first electrode 56a to have increased toughness in the first region RE1. As a result, cracking can be inhibited at the end portion of the first electrode 56a, which is where cracking tends to originate.

For example, when platinum is contained as the metal material forming the first electrode 56a, the density of platinum in the first electrode 56a in the first region RE1 can be made higher than the density of platinum in the first electrode 56a in the second region RE2, which makes it possible to inhibit cracking at the end portion of the first electrode 56a.

Also, when the first electrode 56a has a high lead content percentage, the adhesion between the first electrode 56a and the vibration plate 55 can be increased. This is because it makes it easier for a mixture layer to be formed between the first electrode 56a and the vibration plate 55, the mixture layer being a mixture of lead and a material forming each layer. Thus, because the lead content percentage in the lead-containing layer 56a2 in the second region RE2 is higher than the lead content percentage in the lead-containing layer 56a2 in the first region RE1, the adhesion between the first electrode 56a and the vibration plate 55 can be increased. Then, peeling between the first electrode 56a and the vibration plate 55 can be prevented. Also, the adhesion between the first electrode 56a and the piezoelectric layer 56b can be increased in the second region RE2 as well.

The lead content percentage in the lead-containing layer 56a2 in the first region RE1 preferably increases toward the second region RE2. This advantageously makes it easier to mitigate stress generated between the active portion RA and the non-active portion RN of the piezoelectric element 56 when the piezoelectric element 56 is driven.

The ratio of the lead content percentage in the lead-containing layer 56a2 in the first region RE1 to the lead content percentage in the lead-containing layer 56a2 in the second region RE2 is not limited to a particular ratio, but is preferably less than 1.00. Thus, a/β is preferably less than 1.00 where a is the lead content percentage in the lead-containing layer 56a2 in the first region RE1 and β is the lead content percentage in the lead-containing layer 56a2 in the second region RE2. In other words, a/B is more preferably no less than 0.60 and no more than 0.95. This favorably offers the effect achieved when the lead content percentage in the lead-containing layer 56a2 in the first region RE1 is lower than the lead content percentage in the lead-containing layer 56a2 in the second region RE2.

In the example shown in FIG. 6, the thickness of the lead-containing layer 56a2 in the second region RE2 is substantially constant, whereas the thickness of the lead-containing layer 56a2 in the first region RE1 becomes thinner with distance from the second region RE2. Note that the thickness of the lead-containing layer 56a2 in the first region RE1 may be substantially constant, similarly to the thickness of the lead-containing layer 56a2 in the second region RE2.

The lead-containing layer 56a2 may contain at least one element selected from V, Nb, Ta, Ni, P, As, Sb, and Bi. For example, in a case where the piezoelectric layer 56b contains at least one element selected from V, Nb, Ta, N, P, As, Sb, and Bi, a content percentage of the at least one element in the lead-containing layer 56a2 in the first region RE1 is preferably lower than a content percentage of the at least one element in the lead-containing layer 56a2 in the second region RE2.

In a case where the piezoelectric layer 56b contains at least one element selected from vanadium (V), niobium (Nb), tantalum (Ta), nickel (Ni), phosphorus (P), arsenic (As), antimony (Sb), and bismuth (Bi), oxygen deficit in the piezoelectric layer 56b can be mitigated. As a result, the drive speed for the piezoelectric element 56 can be increased. Also, setting a lower content percentage of the above element for the lead-containing layer 56a2 in the first region RE1 than for the lead-containing layer 56a2 in the second region RE2 can offer the same effect achieved by setting a lower lead content percentage for the lead-containing layer 56a2 in the first region RE1 than for the lead-containing layer 56a2 in the second region RE2.

The thickness of the lead-containing layer 56a2 is not limited to any particular thickness, but is, for example, in the range of no less than 5 nm and no more than 25 nm. The lead-containing layer 56a2 may be a closely packed layer or may be a sparse layer where lead in an elemental or alloyed form or in an oxide, nitride, or oxynitride form is scattered in the shapes of island.

In the first region RE1, the surface of the first electrode 56a which is located opposite from the vibration plate 55 slants relative to the plate surface of the vibration plate 55. An angle θ formed between the surface of the first electrode 56a which is opposite from the vibration plate 55 and the plate surface of the vibration plate 55 is preferably no less than 10 degrees and less than 60 degrees. This can not only make the liquid ejection head 50 compact in size, but also inhibit entry of lead into the first electrode 56a in the first region RE1.

The first mixture layer 56a3 is disposed between the electrode layer 56al and the lead-containing layer 56a2 in the first region RE1 and is formed of a mixed material of lead and the material forming the electrode layer 56a1. The provision of the first mixture layer 56a3 enables further improvement in the adhesion between the first electrode 56a and the vibration plate 55 in the first region RE1. This as a result can inhibit peeling of the first electrode 56a off the vibration plate 55 or the occurrence of cracking. Note that, for illustrative convenience, FIG. 6 distinctly depicts the interface between the first mixture layer 56a3 and the electrode layer 56al and the interface between the first mixture layer 56a3 and the lead-containing layer 56a2, but these interfaces do not have to be distinct.

A thickness t1 of the first mixture layer 56a3 is not limited to any particular thickness, but is, for example, in the range of no less than 5 nm and no more than 30 nm.

The second mixture layer 56a4 is disposed between the electrode layer 56al and the lead-containing layer 56a2 in the second region RE2 and is formed of a mixed material of lead and the material forming the electrode layer 56a1. In the example shown in FIG. 6, the second mixture layer 56a4 is integral with the first mixture layer 56a3 as the same layer. Note that the second mixture layer 56a4 may be separate from the first mixture layer 56a3. Also, for illustrative convenience, FIG. 6 distinctly depicts the interface between the second mixture layer 56a4 and the electrode layer 56al and the interface between the first mixture layer 56a3 and the lead-containing layer 56a2, but these interfaces do not have to be distinct.

A thickness t2 of the second mixture layer 56a4 is preferably larger than the thickness t1 of the first mixture layer 56a3. Thus, the thickness t1 of the first mixture layer 56a3 is preferably smaller than the thickness t2 of the second mixture layer 56a4. This can favorably inhibit both of the occurrence of cracking in the second region RE2 and peeling of the first electrode 56a off the vibration plate 55.

The thickness t2 of the second mixture layer 56a4 is not limited to any particular thickness, but is, for example, in the range of no less than 5 nm and no more than 30 nm.

Note that the first mixture layer 56a3 and the second mixture layer 56a4 are layers with lower lead content percentages than the lead-containing layer 56a2. The lead content percentages in the first mixture layer 56a3 and the second mixture layer 56a4 are measured similarly to the lead content percentages described above.

For example, the first electrode 56a is formed using a film formation technique such as sputtering and processing techniques such as photolithography and etching. Also, lead may be contained into the lead-containing layer 56a2 by, for example, introduction of lead through ion implantation or film formation of a material containing lead. Note that in order for the lead-containing layer 56a2 to have different lead content percentages in the first region RE1 and the second region RE2, the amount of lead introduced for ion implantation may be changed, or the film formation conditions and target may be changed for each region.

The piezoelectric element 56 has the first lead diffusion inhibition layer 56e and the second lead diffusion inhibition layer 56f in addition to the first electrode 56a, the piezoelectric layer 56b, and the second electrode 56c described above.

The first lead diffusion inhibition layer 56e is disposed between the first electrode 56a and the vibration plate 55 in each of the first region RE1 and the second region RE2 and inhibits diffusion of lead from the first electrode 56a to the vibration plate 55. The first lead diffusion inhibition layer 56e contains titanium. The first lead diffusion inhibition layer 56e may contain a metal element other than titanium. Also, titanium contained in the first lead diffusion inhibition layer 56e may be present in an elemental or alloyed form or in an oxide, nitride, or oxynitride form.

A titanium content percentage in the first lead diffusion inhibition layer 56e in the first region RE1 is preferably lower than a titanium content percentage in the first lead diffusion inhibition layer 56e in the second region RE2. When titanium content percentages are measured using, for example, secondary ion mass spectrometry, energy dispersive X-ray analysis, or the like, the titanium content percentage in the first lead diffusion inhibition layer 56e in the first region RE1 is lower than the titanium content percentage in the first lead diffusion inhibition layer 56e in the second region RE2. The titanium content percentages are measured similarly to the lead content percentages described above.

Because the titanium content percentage in the first lead diffusion inhibition layer 56e is higher in the second region RE2, the titanium in the lead-containing layer 56a2 bonds with lead and thereby forms a compound such as TiPbOₓ, which enables a further increase in the adhesion between the first electrode 56a, the first lead diffusion inhibition layer, and the vibration plate 55 in the second region RE2. Because the titanium content percentage in the first lead diffusion inhibition layer 56e is lower in the first region RE1, titanium in the first electrode 56a and the piezoelectric layer 56b is more easily taken into the first lead diffusion inhibition layer 56e to bond with unreacted lead in the formation of a compound of titanium and lead. As a result, in the first region RE1, the adhesion between the first electrode 56a, the first lead diffusion inhibition layer 56e, and the piezoelectric layer 56b can be increased.

A titanium oxide content percentage in the first lead diffusion inhibition layer 56e in the first region RE1 is preferably higher than a titanium oxide content percentage in the first lead diffusion inhibition layer 56e in the second region RE2. This makes the degree of oxidation of the lead-containing layer 56a2 in the first region RE1 higher than the degree of oxidation in the lead-containing layer 56a2 in the second region RE2 and can inhibit oxygen loss from the piezoelectric layer 56b through the first region RE1.

The content percentage of TiO₂ in the first lead diffusion inhibition layer 56e in the first region RE1 is preferably higher than the content percentage of TiO₂ in the first lead diffusion inhibition layer 56e in the second region RE2. TiO₂ is chemically stable compared to titanium oxides of other oxidation numbers. Hence, setting a higher content percentage of TiO₂ for the lead-containing layer 56a2 in the first region RE1 than for the lead-containing layer 56a2 in the second region RE2 can favorably inhibit oxygen loss from the piezoelectric layer 56b through the first region RE1.

The thickness of the first lead diffusion inhibition layer 56e is not limited to any particular thickness, but is, for example, in the range of no less than 1 nm and no more than 10 nm. Note that the first lead diffusion inhibition layer 56e is provided as needed and may be omitted.

The second lead diffusion inhibition layer 56f is disposed between the piezoelectric layer 56b and the vibration plate 55 in a third region RE3 and contains titanium, the third region RE3 being a region, when seen in the lamination direction DL, opposite from the second region RE2 in the crossing direction DC and connected to the first region RE1. Note that the third region RE3 is included in the non-active portion RN.

The size of the third region RE3 in the crossing direction DC is determined based on, e.g., the thickness and width of the first electrode 56a and not limited to any particular size, but is, for example, in the range of no less than 90 nm and no more than 320 nm. Thus, the third region RE3 is a region extending from the end portion of the first electrode 56a outward in the crossing direction DC for a distance in the range of no less than 90 nm and no more than 320 nm. In the example shown in FIG. 6, the size of the third region RE3 in the crossing direction DC is approximately 240 nm.

In the example shown in FIG. 6, the second lead diffusion inhibition layer 56f is integral with the first lead diffusion inhibition layer 56e as the same layer. Note that the second lead diffusion inhibition layer 56f may be separate from the first lead diffusion inhibition layer 56e. Also, for illustrative convenience, FIG. 6 distinctly depicts the interface between the second lead diffusion inhibition layer 56f and the piezoelectric layer 56b, but these interfaces do not have to be distinct.

The titanium content percentage in the second lead diffusion inhibition layer 56f in the third region RE3 is preferably higher than the titanium content percentage in the first lead diffusion inhibition layer 56e in the first region RE1. When titanium content percentages are measured using, for example, secondary ion mass spectrometry, energy dispersive X-ray analysis, or the like, the titanium content percentage in the second lead diffusion inhibition layer 56f in the third region RE3 is higher than the titanium content percentage in the first lead diffusion inhibition layer 56e in the second region RE2.

A comparison between the titanium content percentage in the first lead diffusion inhibition layer 56e in the first region RE1 and that in the second lead diffusion inhibition layer 56f in the third region RE3 is done by a comparison of titanium content percentages measured at the same position in the lamination direction DL. Also, the comparison is preferably done using a titanium content percentage at the center position of the first lead diffusion inhibition layer 56e in the first region RE1 and a titanium content percentage at the center position of the second lead diffusion inhibition layer 56f in the third region RE3. Note that the comparison may be done using the averages of a plurality of titanium content percentages at a plurality of locations in the lamination direction DL or the crossing direction DC.

Thus, lead escaping from the piezoelectric layer 56b in the third region RE3 bonds preferentially with the titanium in the second lead diffusion inhibition layer 56f in the third region RE3, which can inhibit entry of the lead into the first region RE1 and the second region RE2. A titanium content percentage in each of these layers is calculated from the ratio of a titanium content relative to the content of another material contained in the layer.

The thickness of the second lead diffusion inhibition layer 56f is not limited to any particular thickness, but is, for example, in the range of no less than 20 nm and no more than 80 nm. Note that the thickness of the second lead diffusion inhibition layer 56f may be the same as or different from the thickness of the first lead diffusion inhibition layer 56e. The second lead diffusion inhibition layer 56f is provided as needed and may be omitted.

The first lead diffusion inhibition layer 56e and the second lead diffusion inhibition layer 56f are formed using, for example, a film formation technique such as sputtering. Also, the titanium may be contained into the first lead diffusion inhibition layer 56e and the second lead diffusion inhibition layer 56f by, for example, introduction of titanium through ion implantation or film formation of a material containing titanium. In order for the first lead diffusion inhibition layer 56e and the second lead diffusion inhibition layer 56f to have different titanium content percentages, the film formation conditions and target may be changed for each region.

### 2. Modifications

The modes exemplified above can be variously modified. Specific modifications that may be applied to the above-described modes are exemplified below. Note that any of two or more modes selected from the following examples may be combined as needed without conflicting with each other.

### 2-1. Modification 1

In the modes described above, the piezoelectric layer 56b is provided commonly for the plurality of pressure chambers C; however, the present disclosure is not limited to this, and the piezoelectric layer 56b may be divided for the pressure chambers C. Also, the second electrode 56c may be individual electrodes, in which case, the first electrode 56a may be a common electrode, or the first electrode 56a and the second electrode 56c may both be individual electrodes.

### 2-2. Modification 2

In the modes described above, the serial-type liquid ejection apparatus 100 in which the carriage 41 having the liquid ejection head 50 mounted thereto reciprocates is used as an example; however, the present disclosure can also be applied to a line-type liquid ejection apparatus in which the plurality of nozzles N are distributed over the entire width of the medium M.

### 2-3. Modification 3

The liquid ejection apparatus 100 exemplified in the above modes may be employed not only for a device dedicated for printing, but also various other devices such as a facsimile device or a copier device. However, the purpose of the liquid ejection apparatus of the present disclosure is not limited to printing. For example, a liquid ejection apparatus that ejects a solution of a color material may be used as a manufacturing apparatus that produces color filters for liquid crystal display devices. Also, a liquid ejection apparatus that ejects a solution of a conductive material may be used as a manufacturing apparatus that produces wiring and electrodes on wiring boards.

### 3. The Overview of the Present Disclosure

The following supplementarily provides the overview of the present disclosure.

(Supplemental Note 1) A first mode as a preferred example of a liquid ejection head of the present disclosure includes: a piezoelectric element having a first electrode, a piezoelectric layer, and a second electrode and a vibration plate connected to the piezoelectric element, the first electrode, the piezoelectric layer, and the second electrode are laminated in this order in a lamination direction which is a direction directed from the vibration plate to the piezoelectric element, the piezoelectric layer is formed of a piezoelectric material containing lead as a constituent element, the first electrode has an electrode layer and a lead-containing layer disposed between the electrode layer and the vibration plate and containing lead, and when, of two regions arranged in a crossing direction, which is a direction crossing the lamination direction, when seen in the lamination direction, a region farther away from a center of the first electrode is a first region and a region closer to the center of the first electrode is a second region, a first lead content percentage in the lead-containing layer in the first region is lower than a second lead content percentage in the lead-containing layer in the second region.

In the above mode, the lead content percentage in the lead-containing layer in the first region is lower than the lead content percentage in the lead-containing layer in the second region, which enables an increase in the density of the metal material forming the first electrode in the first region. This enables an increase in the toughness of the first electrode in the first region. As a result, cracking at the end portion of the first electrode can be inhibited. Also, because the lead content percentage in the lead-containing layer in the second region is higher than the lead content percentage in the lead-containing layer in the first region, the adhesion between the piezoelectric layer and the vibration plate can be increased. Thus, peeling between the piezoelectric layer and the vibration plate can be prevented.

(Supplementary Note 2) In a second mode as a preferred example of the first mode, the first electrode has a first mixture layer disposed between the electrode layer and the lead-containing layer in the first region and formed of a mixed material of lead and a material forming the electrode layer. The above mode enables further improvement in the adhesion between the first electrode and the vibration plate in the first region. As a result, cracking occurring in the first region can be inhibited.

(Supplementary Note 3) In a third mode as a preferred example of the second mode, the first electrode has a second mixture layer disposed between the electrode layer and the lead-containing layer in the second region and formed of a mixed material of lead and a material forming the electrode layer, and thickness of the first mixture layer is thinner than thickness of the second mixture layer. The above mode can favorably inhibit both cracking occurring in the second region and peeling of the first electrode off the vibration plate.

(Supplementary Note 4) In a fourth mode as a preferred mode of any one of the first to third modes, the piezoelectric element further has a first lead diffusion inhibition layer which is disposed between the first electrode and the vibration plate in each of the first region and the second region and which inhibits diffusion of lead from the first electrode to the vibration plate, the first lead diffusion inhibition layer contains titanium, and a first titanium content percentage in the first lead diffusion inhibition layer in the first region is lower than a second titanium content percentage in the first lead diffusion inhibition layer in the second region. In the above mode, because the titanium content percentage in the first lead diffusion inhibition layer is higher in the second region, the titanium in the lead-containing layer bonds with lead and thereby forms a compound such as TiPbOₓ, and the adhesion between the first electrode, the first lead diffusion inhibition layer, and the vibration plate in the second region can be increased further. Also, because the titanium content percentage in the first lead diffusion inhibition layer is lower in the first region, titanium in the first electrode and the piezoelectric layer is more easily taken into the first lead diffusion inhibition layer to bond with unreacted lead in the formation of a compound of titanium and lead. This as a result can increase the adhesion between the first electrode, the first lead diffusion inhibition layer, and the piezoelectric layer in the first region.

(Supplementary Note 5) In a fifth mode as a preferred example of the fourth mode, a first titanium oxide content percentage in the first lead diffusion inhibition layer in the first region is higher than a second titanium oxide content percentage in the first lead diffusion inhibition layer in the second region. In the above mode, because the degree of oxidation of the lead-containing layer in the first region is higher than the degree of oxidation of the lead-containing layer in the second region, oxygen loss from the piezoelectric layer through the first region can be inhibited.

(Supplementary Note 6) A sixth mode as a preferred example of the fifth mode further includes a second lead diffusion inhibition layer containing titanium and disposed between the piezoelectric layer and the vibration plate in a third region which is, when seen in the lamination direction, a region opposite from the second region in the crossing direction and connected to the first region, a third titanium content percentage in the second lead diffusion inhibition layer in the third region is higher than the first titanium content percentage in the first lead diffusion inhibition layer in the first region. In the above mode, because lead escaping from the piezoelectric layer preferentially bonds with titanium in the third region, entry of lead into the first region can be inhibited.

(Supplementary Note 7) In a seventh mode as a preferred example of any one of the first to sixth modes, the vibration plate has an insulating layer containing zirconium, and the insulating layer is disposed offset to a location closer to the first electrode in a direction of thickness of the vibration plate. The above mode can inhibit entry of lead into the vibration plate.

(Supplementary Note 8) In an eighth mode as a preferred example of any one of the first to seventh modes, the piezoelectric layer contains at least one element selected from V, Nb, Ta, N, P, As, Sb, and Bi, and a first content percentage of the at least one element in the lead-containing layer in the first region is lower than a second content percentage of the at least one element in the lead-containing layer in the second region. In the above mode, when the piezoelectric layer contains at least one element selected from V, Nb, Ta, N, P, As, Sb, and Bi, oxygen deficit in the piezoelectric layer can be mitigated. As a result, drive speed for the piezoelectric element can be increased. Also, setting a lower content percentage of the above element for the lead-containing layer in the first region than for the lead-containing layer in the second region can offer an effect similar to the effect achieved by setting a lower lead content percentage for the lead-containing layer in the first region than for the lead-containing layer in the second region.

(Supplementary Note 9) In a ninth mode as a preferred example of any one of the first to eighth modes, in the first region, an angle formed between a surface of the first electrode which is opposite from the vibration plate and a plate surface of the vibration plate is no less than 10 degrees and less than 60 degrees. The above mode can not only make the liquid ejection head compact in size, but also inhibit entry of lead into the second region.

What is claimed is:

1. A liquid ejection head comprising:
a piezoelectric element having a first electrode, a piezoelectric layer, and a second electrode and
a vibration plate, wherein
the first electrode, the piezoelectric layer, and the second electrode are laminated in this order in a lamination direction which is a direction directed from the vibration plate to the piezoelectric element,
the piezoelectric layer is formed of a piezoelectric material containing lead as a constituent element,
the first electrode has
an electrode layer and
a lead-containing layer disposed between the electrode layer and the vibration plate and containing lead, and
when, of two regions arranged in a crossing direction, which is a direction crossing the lamination direction, when seen in the lamination direction, a region farther away from a center of the first electrode is a first region and a region closer to the center of the first electrode is a second region, a first lead content percentage in the lead-containing layer in the first region is higher than a second lead content percentage in the lead-containing layer in the second region.

2. The liquid ejection head according to claim 1, wherein
the first electrode has a first mixture layer disposed between the electrode layer and the lead-containing layer in the first region and formed of a mixed material of lead and a material forming the electrode layer.

3. The liquid ejection head according to claim 2, wherein
the first electrode has a second mixture layer disposed between the electrode layer and the lead-containing layer in the second region and formed of a mixed material of lead and a material forming the electrode layer, and
thickness of the first mixture layer is thinner than thickness of the second mixture layer.

4. The liquid ejection head according to claim 1, wherein
the piezoelectric element further has a first lead diffusion inhibition layer which is disposed between the first electrode and the vibration plate in each of the first region and the second region and which inhibits diffusion of lead from the first electrode to the vibration plate,
the first lead diffusion inhibition layer contains titanium, and
a first titanium content percentage in the first lead diffusion inhibition layer in the first region is lower than a second titanium content percentage in the first lead diffusion inhibition layer in the second region.

5. The liquid ejection head according to claim 4, wherein
a first titanium oxide content percentage in the first lead diffusion inhibition layer in the first region is higher than a second titanium oxide content percentage in the first lead diffusion inhibition layer in the second region.

6. The liquid ejection head according to claim 1, wherein
the piezoelectric element further has a first lead diffusion inhibition layer which is disposed between the first electrode and the vibration plate in each of the first region and the second region and which inhibits diffusion of lead from the first electrode to the vibration plate,
the first lead diffusion inhibition layer contains titanium oxide, and
a first titanium oxide content percentage in the first lead diffusion inhibition layer in the first region is higher than a second titanium oxide content percentage in the first lead diffusion inhibition layer in the second region.

7. The liquid ejection head according to claim 5, further comprising
a second lead diffusion inhibition layer containing titanium and disposed between the piezoelectric layer and the vibration plate in a third region which is, when seen in the lamination direction, a region opposite from the second region in the crossing direction and connected to the first region, wherein
a third titanium content percentage in the second lead diffusion inhibition layer in the third region is higher than the first titanium content percentage in the first lead diffusion inhibition layer in the first region.

8. The liquid ejection head according to claim 1, wherein
the vibration plate has an insulating layer containing zirconium, and
the insulating layer is disposed offset to a location closer to the first electrode in a direction of thickness of the vibration plate.

9. The liquid ejection head according to claim 1, wherein
the piezoelectric layer contains at least one element selected from V, Nb, Ta, N, P, As, Sb, and Bi, and
a first content percentage of the at least one element in the lead-containing layer in the first region is lower than a second content percentage of the at least one element in the lead-containing layer in the second region.

10. The liquid ejection head according to claim 1, wherein
in the first region, an angle formed between a surface of the first electrode which is opposite from the vibration plate and a plate surface of the vibration plate is no less than 10 degrees and less than 60 degrees.
